(19) United States
(12) Patent Application Publication
(10) Pub. No.: US 2008/0135081 A1
(43) Pub. Date: Jun. 12, 2008

(54) THERMAL INSULATION MATERIALS AND APPLICATIONS OF THE SAME

(75) Inventors: Fred Sharifi, Niskayuna, NY (US); Fazila Seker, Clifton Park, NY (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: GENERAL ELECTRIC COMPANY, Schenectady, NY (US)

(21) Appl. No.: 11/608,291

(22) Filed: Dec. 8, 2006

(51) Int. Cl. H01L 35/02; H01L 35/00

(52) U.S. Cl. 136/207; 136/230

(57) ABSTRACT

A thermally insulated structure comprising a first surface and a second surface is provided. The second surface is disposed in a spaced apart relationship with the first surface to define a gap, within which a layer of thermal insulation is provided. The thermal insulation includes a thermoelectric material.

### BACKGROUND

The invention relates generally to the field of thermal insulation, and in particular to thermal insulation materials that may provide additional functionalities.

A thermal insulator is a material having a sufficiently low thermal conductivity to substantially resist transfer of thermal energy. Thermal insulators or thermal insulation materials are widely used in applications requiring minimal heat transfer. Typical applications may include thermal insulation for buildings, for home appliances such as refrigerators, ovens and the like, and for industrial equipments such as furnaces and chemical reactors. For example, thermal insulation materials are used in aircraft, wherein they provide a thermal barrier when applied to the exterior walls of the aircraft and as conventional thermal insulation where it may be applied along the fuselage to maintain the temperature within the passenger cabin. Conventional applications may require large volumes of insulation materials to provide adequate thermal insulation.

It is desirable to address issues related to application of thermal insulation so as to provide efficient thermal insulation.

### BRIEF DESCRIPTION

According to embodiments of the present invention, a thermally insulated structure is provided. The thermally insulated structure includes a first surface bounding a chamber. A second surface is disposed in a spaced apart relationship with the first surface to define a gap between the first surface and the second surface. The thermally insulated structure further includes a layer of thermal insulation disposed in the gap and in thermal communication with the first surface and the second surface, wherein the thermal insulation comprises a thermoelectric material.

In yet another embodiment of the present invention, a method of generating electrical energy is provided. The method includes providing a first surface bounding a chamber. The method further includes providing a second surface disposed in a spaced apart relationship with the first surface to define a gap between the first surface and the second surface. A layer of thermal insulation is disposed in the gap, wherein the layer of thermal insulation comprises a thermoelectric material and is in thermal communication with the first surface and the second surface, and wherein the layer of thermal insulation comprises a thermoelectric device configured to generate electricity.

### DRAWINGS

These and other features, aspects, and advantages of the present invention will become better understood when the following detailed description is read with reference to the accompanying drawings in which like characters represent like parts throughout the drawings, wherein:

FIG. 1 is an exemplary thermally insulated structure, in accordance with an embodiment of the present invention;

FIG. 2 is an exemplary configuration of a thermoelectric device in yet another embodiment of the invention;

FIG. 3 is an exemplary configuration of a thermoelectric device in yet another embodiment of the invention;

FIG. 4 is an exemplary storage tank, in accordance with some embodiments of the invention;

FIG. 5 is an exemplary application of thermal insulation for a building, according to one embodiment of the invention; and

FIG. 6 is an exemplary fuel tank, according to an embodiment of the invention.

### DETAILED DESCRIPTION

In the following specification and the claims, which follow, reference will be made to a number of terms, which shall be defined to have the following meanings. The singular forms “a”, “an” and “the” include plural referents unless the context clearly dictates otherwise. As used herein, the terms “a layer of thermal insulation” and “thermal insulation” are not construed to be limited to any particular shape or size, as it may be a block of material, a plurality of blocks of material in contact or placed adjacent to each other, or a layer of material arranged in a continuous or discontinuous manner. The term, “thermal insulation”, as used herein refers to thermal insulation materials having a thermal conductivity of less than about 1 W/mK. As used herein, the term “temperature differential” implies a difference in temperature across a thermoelectric material. As used herein, the term “gap” implies the spatial relationship between the first surface and the second surface.

Embodiments of the present invention are generally directed at taking advantage of the low thermal conductivity of thermoelectric materials, and electrical energy generating potential of devices using such materials to provide thermal insulation with the additional functionality of electricity generation. Specifically, embodiments of the present invention are directed at taking advantage of the temperature differential that naturally exists across a thermally insulating material. Thermal insulation that includes a thermoelectric device may enable conversion of this thermal differential into useful electrical energy.

The basic principle behind any thermoelectric device for electrical energy generation is the Seebeck effect. The Seebeck effect states that if a temperature difference exists across the ends of a material, a voltage difference will arise between the ends due to the temperature difference. The Seebeck coefficient (which is a property of the thermoelectric material) is the resulting voltage per degree of temperature difference.

The efficiency of a thermoelectric material is known to depend on material properties through a figure-of-merit (ZT), where,

$$ZT = {S}^{2} T \frac{σ}{λ} \qquad ( 1 )$$

Here, S is the Seebeck coefficient, σ is the electrical conductivity of the thermoelectric material, λ is the thermal conductivity of the thermoelectric material and T is the temperature at which the Seebeck coefficient, electrical conductivity and thermal conductivity are measured. A material having a high Seebeck coefficient, a high electrical conductivity and low thermal conductivity will have a high figure-of-merit. Typically, figure-of-merit is measured as an average figure-of-merit (ZT_{avg}), where T_{avg} is the temperature difference between the hot and cold side. Embodiments of the present invention take advantage of thermoelectric material, wherein the thermoelectric material has an average figure-of-merit greater than about 0.1.

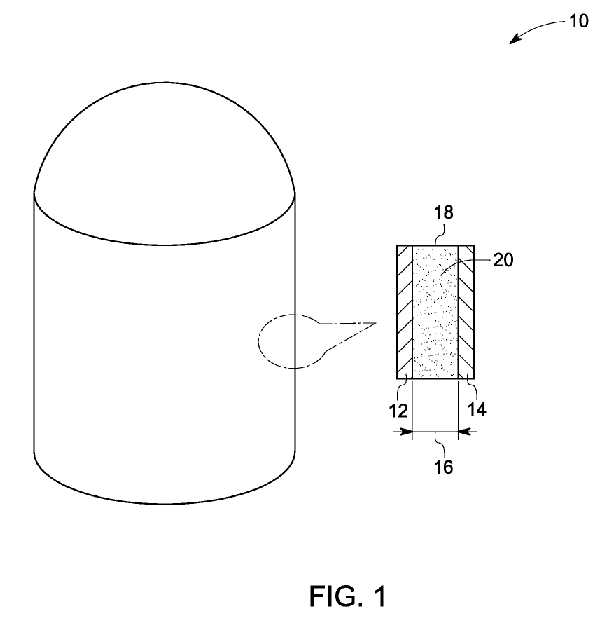

Turning now to the figures, FIG. 1 is a thermally insulated structure 10, according to embodiments of the invention. The thermally insulated structure 10, in the illustrated embodiment, is composed of a double walled structure, having a first surface 12 bounding a chamber (not shown) of which the temperature is to be maintained. A second surface 14 is disposed in a spaced apart relationship with the first surface 12 to define a gap 16 between the first surface 12 and the second surface 14. The first surface 12 and the second surface 14 are thermally conductive.

A layer of thermal insulation 18 is disposed in the gap 16 and is in thermal communication with the first surface 12 and the second surface 14. The layer of thermal insulation 18 comprises a thermoelectric material 20. As will be appreciated, the thermoelectric material 20 due to its low thermal conductivity may advantageously provide thermal insulation.

Example thermoelectric materials 20 comprise at least one species selected from the group consisting of antimonides, arsenides, tellurides, germanides, or any combinations thereof. Exemplary such species include, but are not limited to, binary, ternary and quaternary compounds of semiconducting materials, heavy effective mass alloys including, but not limited to Half-Heusler alloys, and composite structures. Exemplary semiconducting materials include, but are not limited to, indium-antimony-based alloys, indium-arsenic-based-alloys, lead-tellurium-based alloys, lanthanum-tellurium-based alloys, bismuth-tellurium-based alloys, bismuth-antimony-based alloys, silicon-germanium-based alloys, zinc-based alloys or other III-V, IV, IV-VI, and II-VI semiconductors, or any combinations thereof.

The thermoelectric material 20 may have a particular temperature range at which it may exhibit maximum figure-of-merit. Depending on the temperature differential of the application a suitable thermoelectric material 20 may be chosen. For example, for a temperature range of about −100 degrees Celsius to about 25 degrees Celsius, a thermoelectric material such as bismuth or bismuth antimonide may be utilized, as they exhibit their maximum figure-of-merit at this temperature range.

In certain embodiments, the thermoelectric material 20 comprises a nanostructured material. The thermoelectric figure-of-merit is typically greater for a nanostructured material as compared to the corresponding non-nanostructured material. Examples of nanostructured material include, but are not limited to, a nanowire, a nanotube, a nanoparticle, a nanodot, a nanolayer, a nanocomposite or any combinations thereof. In some embodiments, the nanostructured material may include a plurality of nanowires. The plurality of nanowires includes, but is not limited to, one-dimensional nanowires, segmented nanowires, and zero-dimensional superlattice nanowires. In some embodiments, the length of the nanowires is in a range from about 1 micrometer to about 1000 micrometers. In certain embodiments, the length of the nanowires is in a range from about 1 micrometer to about 500 micrometers. Further, the diameter of the nanowires is in a range from about 1 nanometer to about 500 nanometers. In some embodiments, the nanostructured material may be a single layer of nanostructured material and, in certain embodiments, it may be a multiple layer of nanostructured material.

In certain embodiments, the thermoelectric material 20 comprises a superlattice. A superlattice is a periodic structure generally consisting of several to hundreds of alternating thin film layers of semiconductor material where each layer is typically between about 10 and 500 Angstroms thick. The superlattice may be formed by growing on lattice-matched substrates and may advantageously reduce the thermal conductivity and thus may result in improved figure-of-merit.

In some embodiments, the thermoelectric material 20 comprises a porous material. The porous material may advantageously be used for applications requiring low-weight thermal insulation. Moreover, porous thermoelectric material may exhibit lower thermal conductivity compared to dense material of similar composition. In some embodiments, the porous material has a feature size in the range of about 5 nanometers to about 100 nanometers in at least one dimension. In certain embodiments, the feature size is in a range of about 5 nanometers to about 50 nanometers in at least one dimension. Exemplary such features include, but are not limited to, walls surrounding the pores of the porous material, in which case the feature size refers to the wall thickness.

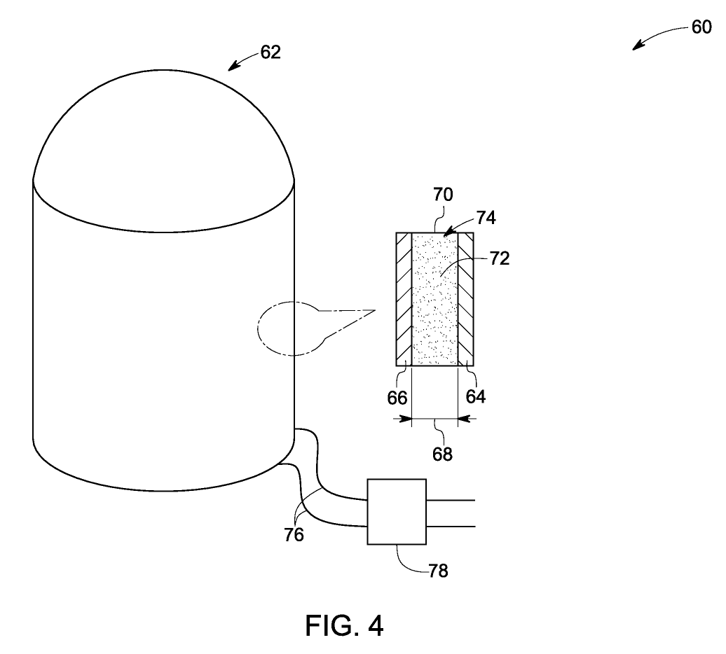

According to embodiments of the invention, the thermally insulated structure 10 is applicable in any setting where a temperature differential is designed to be maintained across the layer of thermal insulation 18. In some embodiments, the thermally insulated structure 10 comprises at least a portion of a vehicle. For example, the vehicle may be an aircraft and the thermally insulated structure 10 may be all or some portion of the aircraft, such as a passenger cabin of the aircraft. In some embodiments, the thermally insulated structure 10 is a storage tank. Example storage tanks include, but are not limited to, a fuel tank of a vehicle, a cryogenic materials storage tank, or a water heater tank. In some embodiments, the thermally insulated structure 10 comprises a component of a turbine assembly. Exemplary components of the turbine assembly include, but are not limited to, a combustor, duct, transition piece, stator, rotor, blade, vane and any combinations thereof. In some embodiments, the thermally insulated structure 10 comprises a household appliance such as, but not limited to, an oven, a refrigerator, a heater, a dishwasher or any combinations thereof. The thermally insulated structure 10 may further comprise other components, and will be described in detail with reference to the FIGS. 4-6.

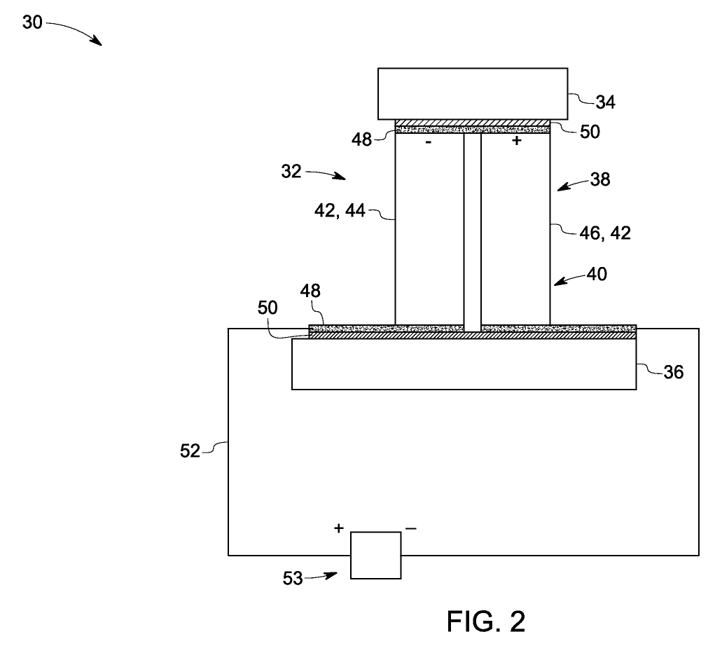

In some embodiments, the thermally insulated structure 10 includes a thermoelectric device configured to generate electricity. The thermoelectric device may include a single thermoelectric material or more than one thermoelectric material arranged in a number of configurations so as to provide maximum efficiency in that temperature range. A representative embodiment of one such set-up is shown in FIG. 2.

FIG. 2 is an exemplary configuration of a thermoelectric device 32, in accordance with embodiments of the invention. A thermally insulated structure 30 comprises a first surface 34 and a second surface 36. As used herein, the first surface 34 and the second surface 36, are not construed to be limited to any shape or size as they may be a single layer, multiple layers, block of material, a closed structure or an open structure.

In the thermally insulated structure 30, the first surface 34 is spaced apart from the second surface 36 to define a gap 38. A layer of thermal insulation 40 comprising thermoelectric material 42 is in thermal communication with the first surface 34 and the second surface 36, and is disposed in the gap 38. Further, the material filling of the gap 38 may also include conventional thermal insulation materials, such as, for example, fiberglass insulation. In one embodiment, the layer of thermal insulation 40 contains no metal; metal is typically detrimental to insulation materials due to the high thermal conductivity of most metals.

The thermoelectric device 32 forms part of the layer of thermal insulation 40. In some embodiments, the thermoelectric device 32 is composed of a thermoelectric leg comprising thermoelectric material 42. In the illustrated embodiment, the thermoelectric device 32 is made of two thermoelectric legs, where each of the legs comprises a n-type semiconductor and a p-type semiconductor, respectively, and are also otherwise termed as n-type segment 44 and p-type segment 46, respectively. In the thermoelectric device 32, the n-type segments 44 and the p-type segments 46 may be arranged in a number of configurations based on the desired properties. The desired properties may include a total power output of the device 32. In some embodiments, the n-type segment 44 and the p-type segment 46 may comprise a nanostructured thermoelectric material. Devices based on such nanostructures are described, for example, in commonly owned U.S. patent application Ser. No. 11/138,615, filed on 26 May 2005.

The n-type segment 44 and the p-type segment 46 are placed between the first surface 34 and the second surface 36. The first surface 34 is at a first temperature, while the second surface 36 is at a second temperature. The first temperature is not equal to the second temperature. In the illustrated embodiment, the first temperature is lower than the second temperature. In certain embodiments, the first temperature is greater than the second temperature.

In this embodiment, the n-type segment 44 is connected electrically in series and thermally in parallel to the p-type segment 46 through an electrical conductor 48. The electrical conductor 48 may advantageously facilitate conduction of electricity between the n-type segment 44 and the p-type segment 46 of the thermoelectric device 32. Optionally, electrical insulators 50 are provided between the electrical conductor 48 and the first surface 34, and between the electrical conductor 48 and the second surface 36. Electrical insulators 50 may prevent electrical leakage to the surfaces 34 and 36 and it additionally serves as a good thermal conductor by transferring heat between the surfaces 34 and 36, and the n-type and p-type segments 44 and 46. An electrical lead 52 is connected to the p-type segment 44 while the other end of the electrical lead 50 is connected to the n-type segment 42.

During operation of the thermoelectric device 32, the temperature differential that exists across the layer of thermal insulation 40 due to the difference in temperature between the first surface 34 and the second surface 36 is advantageously utilized to generate electric power by the Seebeck effect. The electricity generated is led out through the electrical lead 52 to a power management module 53. The electric current flows from the p-type segment 46 to the power management module 53. Further, a number of such thermoelectric devices 32 may be connected in series to form a thermoelectric module with increased power output. The electricity generated may be utilized to run a variety of applications and some of these applications are described with reference to FIGS. 4-6.

Exemplary electrical conductors 48 include, but are not limited to, metals such as aluminum and copper, and highly doped semiconductors. Exemplary electrical insulators 50 include, but are not limited to, aluminum nitride and silicon carbide.

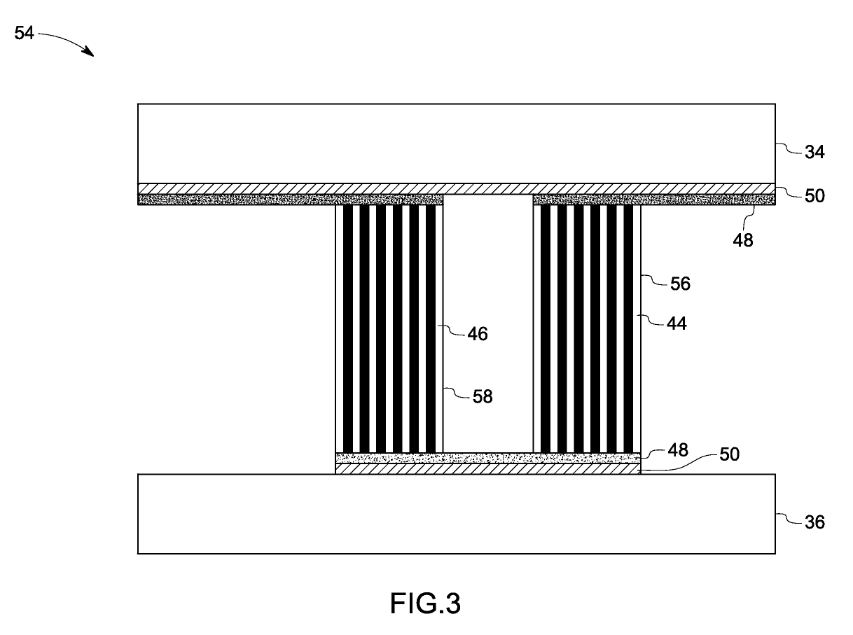

FIG. 3 illustrates yet another exemplary configuration of the n-type segments 44 and the p-type segments 46 in a thermoelectric device 54. In the illustrated embodiment, a number of n-type nanowire segments 44 are connected electrically in parallel to form an n-type thermoelement 56. The p-type nanowire segments 46 are connected electrically in parallel to form a p-type thermoelement 58. Further, the n-type thermoelement 56 may be connected electrically in series to the p-type thermoelement 58.

As noted above, the n-type thermoelement 56 and the p-type thermoelement 58 are sandwiched between the first surface 34 and the second surface 36. Electrical insulators 50 and electrical conductors 48 may be provided between the n-type thermoelement 56 and the p-type thermoelement 58 and the first surface 34, and between the n-type thermoelement 56 and the p-type thermoelement 58 and the second surface 36. The thermoelectric device 54 generates electrical energy proportional to a difference in temperature between the first surface 34 and the second surface 36 due to the Seebeck effect and may be led out through electrical leads (not shown).

In yet another embodiment, the thermoelectric device may have a segmented structure, wherein more than one thermoelectric material composition is used to construct each of the p-type segments 46 and the n-type segments 44. A segmented structure may advantageously provide a higher figure-of-merit by coupling thermoelectric material compositions having maximum efficiency at a particular temperature range as compared to a single thermoelectric material that is used across a temperature differential. In one embodiment, the segmented structure may be obtained by varying the degree of doping across similar thermoelectric material compositions. In some embodiments, a cascade structure may be provided by stacking more than one thermoelectric device, such that the temperature difference across each of the stacked thermoelectric devices is a fraction of the total temperature difference across the layer of thermal insulation. Further, each of the thermoelectric devices may consist of more than one thermoelectric material composition. The stacked thermoelectric device may be connected electrically in series to obtain maximum power output.

In the thermoelectric device 54, the n-type segments 44 and the p-type segments 46 may be arranged in a number of configurations based on the desired properties. With an increase in the number of n-type or p-type segments the electric power generated will increase which in turn may increase the power output of the thermoelectric device. One or more of these configurations may be applied to a particular application and are described in detail with reference to FIGS. 4-6. Further, as above, the layer of thermal insulation may also include conventional thermal insulation materials, such as, for example, fiberglass insulation.

FIG.4 is an exemplary storage tank 60, such as, for example, a tank for the storage of a cryogenic liquid, in accordance with embodiments of the invention. The storage tank 60 includes a housing 62. The housing 62 of the storage tank 60 comprises a double-walled structure having a first surface 64 and a second surface 66. Further, the first surface 64 and the second surface 66 may have additional layers or coatings that may provide other functionalities. The first surface may be fabricated of a material such as, but not limited to, stainless steel or aluminum. The second surface 66 of the housing 62 defines a chamber (not shown) within which a material is stored.

The first surface 64 is spaced apart from the second surface 66 to define a gap 68 having a volume. According to embodiments of the invention, a layer of thermal insulation 70 is disposed in the gap 68 and is in thermal communication with the first surface 64 and the second surface 66. In one embodiment, the layer of thermal insulation 70 substantially surrounds the chamber. As used herein, the term “substantially” refers to greater than about 50% of the chamber surface area. In some embodiments, greater than about 70% of the chamber surface area is surrounded, and in one particular embodiment, greater than about 90% of the chamber surface area is surrounded. The layer of thermal insulation 70 comprises a thermoelectric material 72. The thermoelectric material 72 may form part of a thermoelectric device 74 configured to generate electricity, as shown in one or more of the configurations described previously.

The temperature of the chamber is maintained at least in part by the layer of thermal insulation 70 comprising the thermoelectric material 72. When material being stored in the chamber is a cryogenic material, the temperature of the chamber is maintained within a narrow temperature range as might be required for storage of cryogenic materials. For example, a chamber containing liquid hydrogen is typically maintained at a temperature range of about −250 degrees Celsius to about −256 degrees Celsius. In some embodiments, the cryogenic material is a cryogenic liquid. Exemplary cryogenic liquids include, but are not limited to, helium, hydrogen, nitrogen, argon, oxygen and methane.

The temperature of the first surface 64, otherwise termed as first temperature, is typically near or at the ambient temperature, for example at about 25 degrees Celsius. The second surface 66 is at a second temperature, where the second temperature may be near or at the ambient temperature of the contents of the chamber. Typically, the temperature of the chamber storing cryogenic material is lower than about −100 degrees Celsius.

During operation, the thermoelectric device 74 advantageously utilizes the temperature differential across the layer of thermal insulation 70 that exists due to the difference in temperatures between the second surface 66 and the first surface 64 to generate useful electrical energy. The power output from the thermoelectric device 74 may be manipulated by selecting suitable configuration of the n-type segments and the p-type segments, as noted above. The power output may also depend on the choice of the thermoelectric material 72. The temperature differential that may exist across the layer of thermal insulation 70 is quite substantial, in this embodiment, due to the large difference in temperature between the first surface 64 and the second surface 66. The efficiency of the device 74 may be enhanced by selecting a suitable thermoelectric material 72 having high figure-of-merit in this particular temperature range. In some embodiments, bismuth or bismuth antimonide is utilized in the layer of thermal insulation 70. In certain other embodiments, a semiconductor material or any associated alloys exhibiting similar band gap as bismuth is employed.

Further, the storage tank 60 includes electrical leads 76 from the layer of thermal insulation 70 to transfer the electrical energy generated to a power management module 78. The power management module 78, in some embodiments, comprises a power storage device (not shown), such as a storage battery.

The power management module 78 is in electrical communication with the layer of thermal insulation 70 through the electrical leads 76 and the electricity generated by the thermoelectric device 74 is transferred for useful applications. In some embodiments, the power management module 78 is in electrical communication with an interface of a component. The component may draw the electricity generated by the thermoelectric device 74 through the interface to drive electrical devices. For example, the component may be used to power sensors (not shown) within the chamber, such as, a level detector to detect the volume of the cryogenic material in the storage tank 60.

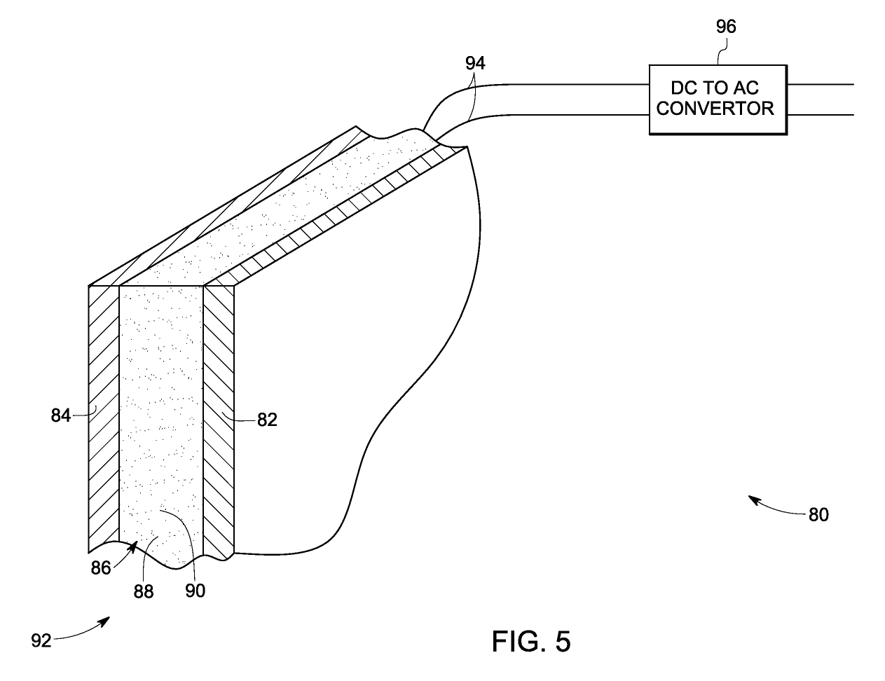

A layer of thermal insulation, according to some embodiments of the invention, is utilized for thermal insulation application for a building. FIG. 5 is an exemplary thermal insulation application for a building 80. The building 80 includes a double walled structure comprising a first surface 82 and a second surface 84. The first surface 82 is spaced apart from the second surface 84 to define a gap 86 between the first surface 82 and the second surface 84. A layer of thermal insulation 88 comprising a thermoelectric material 90 is disposed in the gap 86 and is in thermal communication with the first surface 82 and the second surface 84. The layer of thermal insulation 88 may also include conventional thermal insulation materials. The thermoelectric material 90 may form part of a thermoelectric device 92 configured to generate electricity, as shown in one or more of the configurations described previously.

The first surface 82 defines a chamber (not shown) which corresponds to the interior of the building 80. The first surface 82 is at a first temperature that may be near or at the ambient temperature of the interior of the building 80. In one example, the temperature of the interior of the building is maintained at about 25 degrees Celsius. The layer of thermal insulation 88 provides insulation to the interior of the building 80. In some embodiments, the thermoelectric material 90 is coupled with conventional thermal insulation materials, such as fiberglass to provide thermal insulation. The second surface 84 is at a second temperature which is typically near or at the ambient temperature of the outside of the building 80. Typically, such temperatures may vary from about 45 degrees Celsius to about −25 degrees Celsius.

The thermoelectric device 92 may advantageously employ the temperature differential across the layer of thermal insulation 88 to generate electrical energy. Electrical leads 94 supplied to the layer of thermal insulation 88 drain the electricity generated from a direct current (DC) to alternating current (AC) converter 96. The DC to AC converter 96 converts the output from the layer of thermal insulation 88, which is of direct current, to an alternating current useful for household applications. In some embodiments, the DC to AC converter 96 drives one or more electrical appliances and instruments such as, but not limited to, a temperature sensor, a fire alarm, a burglar alarm, or kitchen appliances.

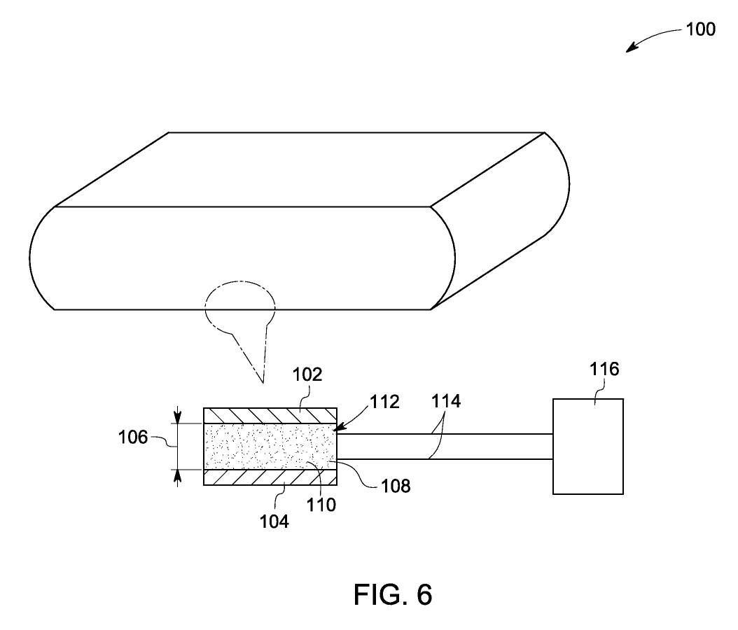

According to embodiments of the invention, an exemplary fuel tank 100 for an aircraft is shown in FIG. 6. The fuel tank 100 is applicable in any vehicle where there is a temperature differential between the outside environment and the inside environment. Exemplary such vehicles include an air-based, a land-based, or a sea-based vehicle such as, but not limited to, an automobile, a ship, or a locomotive.

The fuel tank 100 comprises a double-layered structure having a first surface 102 and a second surface 104. The first surface 102 and the second surface 104 are spaced apart from each other to define a gap 106 between the two. The first surface 102 defines a chamber (not shown) within which the fuel is stored. A layer of thermal insulation 108 comprising a thermoelectric material 110 is disposed in the gap 106. The layer of thermal insulation 108 is in thermal communication with the first surface 102 and the second surface 104. The thermoelectric material 110 may form part of a thermoelectric device 112 configured to generate electricity, as shown in one or more of the configurations described previously.

The thermoelectric material 110 may be chosen based on the application of the fuel tank 100. For example, in aircraft applications it is desirable that the contribution from the weight of the fuel tank 100 to the overall weight of the aircraft is minimal. In such type of applications, a porous thermoelectric material may be utilized. In one embodiment, the porous thermoelectric material structures may be made from bulk thermoelectric material as described for example in commonly owned U.S. patent application Ser. No. 11/433,087, filed on 12 May 2006.

The second surface 104 is at a first temperature that is typically near or at the ambient temperature to which the aircraft fuel tank 100 is exposed. The first surface 102 is at a second temperature near or at the temperature at which the aircraft fuel is stored.

The thermoelectric device 112 may advantageously utilize the temperature differential that exists across the layer of thermal insulation 108 to generate electricity using the Seebeck effect. The layer of thermal insulation 108 includes electrical leads 114 which are in electrical communication with a power management module 116. In one embodiment, the power management module 116 comprises a battery. In certain embodiments, the power management module 116 is further connected to a DC to DC converter (not shown) to step up or step down the voltage. The power management module 116, in some embodiments, is in electrical communication with an interface of a component (not shown). The component is configured to receive the power at the interface, wherein the power received is used to drive more than one electrical device requiring low power input such as, but not limited to, low energy consumption lighting needs, smoke and fire alarms, and gas quality monitors.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A thermally insulated structure comprising:
a first surface bounding a chamber;
a second surface disposed in a spaced apart relationship with the first surface to define a gap between the first surface and the second surface; and
a layer of thermal insulation disposed in the gap and in thermal communication with the first surface and the second surface, wherein the layer of thermal insulation comprises a thermoelectric material.

2. The thermally insulated structure of claim 1, wherein the structure further comprises a thermoelectric device configured to generate electricity, the thermoelectric device comprising the thermoelectric material.

3. The thermally insulated structure of claim 1, wherein the thermoelectric material has an average figure-of-merit greater than about 0.1.

4. The thermally insulated structure of claim 2, wherein the thermoelectric device comprises at least one p-type segment and at least one n-type segment, wherein the at least one p-type segment and the at least one n-type segment are connected electrically in series and thermally in parallel.

5. The thermally insulated structure of claim 1, wherein the thermoelectric material comprises a nanostructured material.

6. The thermally insulated structure of claim 5, wherein the nanostructured material comprises nanowires, nanotubes, nanoparticles, nanodots, nanolayers, nanocomposites or any combinations thereof.

7. The thermally insulated structure of claim 1, wherein the thermoelectric material comprises at least one species selected from the group consisting of indium-antimony-based alloys, indium-arsenic-based-alloys, lead-tellurium-based alloys, lanthanum-tellurium-based alloys, bismuth-tellurium-based alloys, bismuth-antimony-based alloys, silicon-germanium-based alloys, zinc-based alloys, III-V, IV, IV-VI, and II-VI semiconductors, Half-Heusler alloys and any combinations thereof.

8. The thermally insulated structure of claim 1, wherein the thermoelectric material comprises a porous material.

9. The thermally insulated structure of claim 8, wherein the porous material has a feature size in the range from about 5 nanometers to about 100 nanometers.

10. The thermally insulated structure of claim 1, wherein the structure further comprises a power management module disposed in electrical communication with the thermal insulation.

11. The thermally insulated structure of claim 10, wherein the power management module comprises a power storage device.

12. The thermally insulated structure of claim 10, wherein the power management module comprises a DC to AC converter, a DC to DC converter or any combinations thereof.

13. The thermally insulated structure of claim 10, wherein the structure further comprises a component configured to receive a power input at an interface, and wherein the power management module is in electrical communication with the interface of the component.

14. The thermally insulated structure of claim 1, wherein the structure is at least a portion of a vehicle.

15. The thermally insulated structure of claim 14, wherein the vehicle is an aircraft.

16. The thermally insulated structure of claim 14, wherein at least the portion of the vehicle is an aircraft passenger cabin.

17. The thermally insulated structure of claim 1, wherein the structure is a storage tank.

18. The thermally insulated structure of claim 17, wherein the storage tank is a fuel tank.

19. The thermally insulated structure of claim 17, wherein the storage tank is a cryogenic liquid storage tank.

20. The thermally insulated structure of claim 17, wherein the storage tank is a water heater tank.

21. The thermally insulated structure of claim 1, wherein the structure comprises a component of a turbine assembly.

22. The thermally insulated structure of claim 21, wherein the component of the turbine assembly is selected from a group consisting of a combustor, duct, transition piece, stator, rotor, blade, vane and any combinations thereof.

23. The thermally insulated structure of claim 1, wherein the structure comprises a household appliance.

24. The thermally insulated structure of claim 23, wherein the household appliance comprises an oven, a refrigerator, a heater, a dishwasher or any combinations thereof.

25. The thermally insulated structure of claim 1, wherein the structure is a building.

26. The thermally insulated structure of claim 1, wherein the structure is configured to maintain a temperature of the chamber that is higher than an ambient temperature.

27. The thermally insulated structure of claim 1, wherein the structure is configured to maintain a temperature of the chamber that is lower than an ambient temperature.

28. A method of generating electrical energy comprising:
providing a first surface bounding a chamber;
providing a second surface disposed in a spaced apart relationship with the first surface to define a gap between the first surface and the second surface; and
disposing a layer of thermal insulation in the gap, wherein the layer of thermal insulation comprises a thermoelectric material and is in thermal communication with the first surface and the second surface, and wherein the layer of thermal insulation comprises a thermoelectric device configured to generate electricity.
